(19) United States
(12) Patent Application Publication
(10) Pub. No.: US 2008/0248648 A1
(43) Pub. Date: Oct. 9, 2008

(54) DEPOSITION PRECURSORS FOR SEMICONDUCTOR APPLICATIONS

(76) Inventors: David M. Thompson, East Amherst, NY (US); Joan Elizabeth Geary, Lakeview, NY (US)

Correspondence Address: PRAXAIR, INC.;LAW DEPARTMENT - M1 557, 39 OLD RIDGEBURY ROAD, DANBURY, CT, 06810-5113, US

(21) Appl. No.: 12/060,336

(22) Filed: Apr. 1, 2008

Related U.S. Application Data
(60) Provisional application No. 60/922,220, filed on Apr. 6, 2007.
(60) Provisional application No. 61/040,289, filed on Mar. 28, 2008.

(51) Int. Cl. H01L 21/44; C07F 15/06

(52) U.S. Cl. 438/681; 556/140; 257/E21.17

(57) ABSTRACT

This invention relates to organometallic compounds comprising at least one metal or metalloid and at least one substituted anionic 6 electron donor ligand having sufficient substitution (i) to impart decreased carbon concentration in a film or coating produced by decomposing said compound, (ii) to impart decreased resistivity in a film or coating produced by decomposing said compound, or (iii) to impart increased crystallinity in a film or coating produced by decomposing said compound. The organometallic compounds are useful in semiconductor applications as chemical vapor or atomic layer deposition precursors for film depositions.

### RELATED APPLICATIONS

This application claims the benefit of U.S. Provisional Application Ser. No. 60/922,220, filed on Apr. 6, 2007 and U.S. Provisional Application Ser. No. 61/040,289, filed on Mar. 28, 2008; both of which are incorporated herein by reference.

### FIELD OF THE INVENTION

This invention relates to organometallic compounds and a method for producing a film or coating from organometallic precursor compounds. The organometallic compounds have the ability to reduce carbon incorporation in deposition films and increase thermal stability. In particular, the organometallic compounds have an enabling advantage for several semiconductor applications such as cobalt and cobalt silicide deposition for contact applications.

### BACKGROUND OF THE INVENTION

The deposition of metallic films of cobalt and cobalt silicide are of considerable interest for a variety of semiconductor applications. Cobalt silicide is of particular interest for its use in forming electrical contacts on the source/drain and gate regions of semiconductor transistors. Its high thermal and chemical stability in conjunction with its low electrical resistance make it ideal. Cobalt silicide can be effectively formed by the deposition of cobalt metal on polysilicon (gate) or silicon (source/drain) followed by subsequent annealing. It has a low consumption of silicon when forming the cobalt silicide during the anneal process which is also attractive to the semiconductor manufacturers.

Current deposition solutions involve physical vapor deposition (PVD), chemical vapor deposition (CVD) and atomic layer deposition (ALD). PVD processes for depositing cobalt suffer from poor step coverage and agglomeration on aggressive geometries. This can lead to an irregular cobalt (Co) layer thickness which in turn leads to irregular thicknesses of the cobalt silicide layer which negatively impacts transistor performance reliability. CVD and ALD processes typically lead to the incorporation of impurities into semiconductor films such as carbon (C), oxygen (0) and nitrogen (N) that are introduced from the precursor compound. These impurities can strongly impact on the viability of the formation of the desired electrical contact layer and can lead to the formation of an SiO₂ layer between the cobalt and silicon layers which subsequently impedes the formation of cobalt silicide during anneal processes.

CpCo(CO)₂ or dicarbonyl(cyclopentadienyl)cobalt (I) is a CVD precursor that finds regular use in Co deposition, but suffers from significant carbon incorporation. It is an attractive precursor material in that it is relatively inexpensive to synthesize and a significant amount of data is available related to its deposition.

Various attempts have been made in the related art to reduce the carbon incorporation. Conventional approaches to eliminating carbon incorporation in films generally fall into four categories: 1) use of a carbon free deposition technology, 2) modification of the deposition source to reduce the carbon available in the source, 3) modification of the deposition source to eliminate M-C bonds, 4) post deposition treatment of a film to remove C from the film.

Carbon free deposition technology includes but is not limited to the use of halide based CVD precursors, PVD and molecular beam epitaxy (MBE) based approaches. For reasons listed above (conformality, step coverage and agglomeration) PVD sources free of carbon are not always the preferred choice. Halide based precursors can present other issues in that the halide ligand can poison and or etch adjacent films during deposition.

U.S. Pat. No. 7,172,967 B2 to Samsung discloses the use of a precursor referred to as CCTBA Co₂(CO)₆((CH₃)₃C—C≡C—H), to generate Co films with low carbon levels by CVD at temperatures between 120 and 210 degrees Celsius. The temperature of a substrate can impact the rate at which precursor molecules diffuse into narrow high aspect ratio features and generally the diffusion rate increases as molecules diffuse into the trenches. Samsung has also independently reported that they observe the best electrical properties in cobalt silicide films when they deposit a PVD layer of Co followed by a CVD layer of Co from CCTBA, followed by deposition of Ti on the Co, followed by an anneal. This suggests that the quality of the CVD Co that is deposited at these temperatures is not sufficient for optimal electrical properties and may be attributable to unacceptably high levels of carbon or other impurities.

In U.S. Patent Application Publication No. 2007/60037391 A1 and Gordon, et. al., Nature Materials, Vol. 2, P. 749, November 2003, the production of compounds that do not involve any M-C bonds, but rather involve M-N bonds are discussed. These species involve complex syntheses and have the potential to form nitrides of either the metal in question or a nitride/oxynitride on the substrate on which they are being initially deposited. Typically they also suffer from high costs associated with the ligand synthesis that challenges their potential use in semiconductor applications.

Finally, post deposition treatment of a film, or treatment of a film during growth to scavenge incorporated carbon into the film environment may be pursued as an approach to limit carbon incorporation. Typically this involves the use of oxygen or plasmas. These strong chemical environments can have a negative impact on other films and damage the local environment during film deposition and, as a result, these are usually considered as a measure of last resort when precursor modifications do not yield appropriate films, and PVD or halide based precursors cannot be used in the deposition environment.

To overcome the disadvantages associated with the related art, it is an object of this invention to provide precursors that reduce the carbon incorporation and exhibit increased thermal stability.

It is another object of the invention to provide methods of altering the cyclopentadienyl (Cp) ligand to reduce carbon incorporation in transition metal films derived from Cp based transition metal precursors.

It is a further object of the invention that the films can be deposited with significantly less carbon at deposition temperatures in the 300-500° C. range that exhibit low resistivities and good crystallinity. In situations where some carbon contamination provides benefit (smoother films for example), the carbon level can be controlled by introducing other carbon sources or by tailoring the deposition environment. Furthermore, the thermal stability of the source suggests that in the case of Co and/or Ni the possibility exists that the precursor could be used to directly form CoSi₂ on silicon or polysilicon by depositions at the temperatures required to form these silicides (e.g., 400-500° C.).

The synthetic methodology and materials required for producing these precursors are relatively inexpensive suggesting a potential significant advantage in cost of ownership versus other technologies.

Other objects and advantages of this invention will become apparent to one of ordinary skill in the art upon review of the specification, drawings and claims appended hereto.

### SUMMARY OF THE INVENTION

This invention relates in part to a compound comprising at least one metal or metalloid and at least one substituted anionic 6 electron donor ligand having sufficient substitution (i) to impart decreased carbon concentration in a film or coating produced by decomposing said compound, (ii) to impart decreased resistivity in a film or coating produced by decomposing said compound, or (iii) to impart increased crystallinity in a film or coating produced by decomposing said compound. The at least one substituted anionic 6 electron donor ligand can be fully or partially substituted.

This invention also relates in part to a compound comprising at least one metal or metalloid; at least one substituted anionic 6 electron donor ligand having sufficient substitution (i) to impart decreased carbon concentration in a film or coating produced by decomposing said compound, (ii) to impart decreased resistivity in a film or coating produced by decomposing said compound, or (iii) to impart increased crystallinity in a film or coating produced by decomposing said compound; and at least one spectator ligand selected from (i) a substituted or unsubstituted anionic 2 electron donor ligand, (ii) a substituted or unsubstituted anionic 4 electron donor ligand, (iii) a substituted or unsubstituted neutral 2 electron donor ligand, or (iv) a substituted or unsubstituted anionic 6 electron donor ligand; wherein the sum of the oxidation number of said metal or metalloid and the electric charges of said at least one substituted anionic 6 electron donor ligand and said at least one spectator ligand is equal to 0. The at least one substituted anionic 6 electron donor ligand can be fully or partially substituted.

This invention further relates in part to compounds represented by the formula (L₁)M(L₂)_{y} wherein M is a metal or metalloid, L₁ is a fully substituted anionic 6 electron donor ligand, L₂ is the same or different and is (i) a substituted or unsubstituted anionic 2 electron donor ligand, (ii) a substituted or unsubstituted anionic 4 electron donor ligand, (iii) a substituted or unsubstituted neutral 2 electron donor ligand, or (iv) a substituted or unsubstituted anionic 6 electron donor ligand; and y is an integer of from 1 to 3; and wherein the sum of the oxidation number of M and the electric charges of L₁ and L₂ is equal to 0.

Typically, M is selected from cobalt (Co), rhodium (Rh), iridium (Ir), nickel (Ni), ruthenium (Ru), iron (Fe) or osmium (Os), L₁ is selected from fully substituted anionic 6 electron donor ligands such as a fully substituted cyclopentadienyl group, a fully substituted cyclopentadienyl-like group, a fully substituted cycloheptadienyl group, a fully substituted cycloheptadienyl-like group, a fully substituted pentadienyl group, a fully substituted pentadienyl-like group, a fully substituted pyrrolyl group, a fully substituted pyrrolyl-like group, a fully substituted imidazolyl group, a fully substituted imidazolyl-like group, a fully substituted pyrazolyl group, and a fully substituted pyrazolyl-like group, and L₂ is selected from (i) substituted or unsubstituted anionic 2 electron donor ligands such as hydrido, halo and an alkyl group having from 1 to 12 carbon atoms (e.g., methyl, ethyl and the like), (ii) substituted or unsubstituted anionic 4 electron donor ligands such as allyl, azaallyl, amidinate and betadiketiminate, (iii) substituted or unsubstituted neutral 2 electron donor ligands such as carbonyl, phosphino, amino, alkenyl, alkynyl, nitrile (e.g., acetonitrile) and isonitrile, and (iv) substituted or unsubstituted anionic 6 electron donor ligands such as a substituted or unsubstituted cyclopentadienyl group, a substituted or unsubstituted cyclopentadienyl-like group, a substituted or unsubstituted cycloheptadienyl group, a substituted or unsubstituted cycloheptadienyl-like group, a substituted or unsubstituted pentadienyl group, a substituted or unsubstituted pentadienyl-like group, a substituted or unsubstituted pyrrolyl group, a substituted or unsubstituted pyrrolyl-like group, a substituted or unsubstituted imidazolyl group, a substituted or unsubstituted imidazolyl-like group, a substituted or unsubstituted pyrazolyl group, and a substituted or unsubstituted pyrazolyl-like group.

This invention yet further relates in part to organometallic precursor compounds represented by the formula above.

This invention also relates in part to a method for producing a film, coating or powder by decomposing an organometallic precursor compound, thereby producing said film, coating or powder; wherein said organometallic precursor compound comprises at least one metal or metalloid and at least one substituted anionic 6 electron donor ligand having sufficient substitution (i) to impart decreased carbon concentration in said film, coating or powder, (ii) to impart decreased resistivity in said film, coating or powder, or (iii) to impart increased crystallinity in said film, coating or powder.

This invention further relates in part to a method for processing a substrate in a processing chamber, said method comprising (i) introducing an organometallic precursor compound into said processing chamber, (ii) heating said substrate to a temperature of about 100° C. to about 600° C., and (iii) reacting said organometallic precursor compound in the presence of a processing gas to deposit a metal-containing layer on said substrate; wherein said organometallic precursor compound comprises at least one metal or metalloid and at least one substituted anionic 6 electron donor ligand having sufficient substitution (i) to impart decreased carbon concentration in said metal-containing layer, (ii) to impart decreased resistivity in said metal-containing layer, or (iii) to impart increased crystallinity in said metal-containing layer.

This invention yet further relates in part to a method for forming a metal-containing material on a substrate from an organometallic precursor compound, said method comprising vaporizing said organometallic precursor compound to form a vapor, and contacting the vapor with the substrate to form said metal-containing material thereon; wherein said organometallic precursor compound comprises at least one metal or metalloid and at least one substituted anionic 6 electron donor ligand having sufficient substitution (i) to impart decreased carbon concentration in said metal-containing material, (ii) to impart decreased resistivity in said metal-containing material, or (iii) to impart increased crystallinity in said metal-containing material.

This invention also relates in part to a method of fabricating a microelectronic device structure, said method comprising vaporizing an organometallic precursor compound to form a vapor, and contacting said vapor with a substrate to deposit a metal-containing film on the substrate, and thereafter incorporating the metal-containing film into a semiconductor integration scheme; wherein said organometallic precursor compound comprises at least one metal or metalloid and at least one substituted anionic 6 electron donor ligand having sufficient substitution (i) to impart decreased carbon concentration in said metal-containing film, (ii) to impart decreased resistivity in said metal-containing film, or (iii) to impart increased crystallinity in said metal-containing film.

This invention further relates in part to mixtures comprising (i) a first organometallic precursor compound comprising at least one metal or metalloid and at least one substituted anionic 6 electron donor ligand having sufficient substitution (i) to impart decreased carbon concentration in a film or coating produced by decomposing said compound, (ii) to impart decreased resistivity in a film or coating produced by decomposing said compound, or (iii) to impart increased crystallinity in a film or coating produced by decomposing said compound, and (ii) one or more different organometallic compounds (e.g., a hafnium-containing, tantalum-containing or molybdenum-containing organometallic precursor compound).

This invention relates in particular to depositions involving fully substituted 6-electron donor anionic ligand-based cobalt precursors. These precursors can provide advantages over the other known precursors, such as imparting decreased carbon concentration, decreased resistivity and/or increased crystallinity in a film or coating produced by decomposing the precursor. These precursors can also provide advantages when utilized in tandem with other ‘next-generation’ materials (e.g., hafnium, tantalum and molybdenum). These cobalt-containing materials can be used for a variety of purposes such as dielectrics, adhesion layers, diffusion barriers, electrical barriers, and electrodes, and in many cases show improved properties (reduced carbon incorporation, thermal stability, desired morphology, less diffusion, lower leakage, less charge trapping, and the like) than the non-cobalt containing films.

The invention has several advantages. For example, the method of the invention is useful in generating organometallic precursor compounds that have varied chemical structures and physical properties. Films generated from the organometallic precursor compounds can be deposited with reduced carbon incorporation, reduced resistivity and increased crystallinity, and a short incubation time, and the films deposited from the organometallic precursor compounds exhibit good smoothness. Films deposited using Cp*CO(CO)₂ exhibit decreased carbon incorporation, decreased resistivity and increased crystallinity, compared to films deposited using CpCo(CO)₂ at the same conditions (e.g., temperature and precursor concentration). These fully 6-electron donor anionic ligand-containing cobalt precursors may be deposited by atomic layer deposition employing a hydrogen reduction pathway in a self-limiting manner. Such fully substituted 6-electron donor anionic ligand-containing cobalt precursors deposited in a self-limiting manner by atomic layer deposition may enable conformal film growth over high aspect ratio trench architectures in a reducing environment.

The organometallic precursors of this invention may exhibit different bond energies, reactivities, thermal stabilities, and volatilities that better enable meeting integration requirements for a variety of thin film deposition applications. Specific integration requirements include reactivity with reducing process gases, good thermal stability, and moderate volatility. The precursors do not introduce high levels of carbon into the film.

An economic advantage associated with the organometallic precursors of this invention is their ability to enable technologies that permit continued scaling. Scaling is the primary force responsible for reducing the price of transitors in semiconductors in recent years.

A preferred embodiment of this invention is that the organometallic precursor compounds may be liquid at room temperature. In some situations, liquids may be preferred over solids from an ease of semiconductor process integration perspective. The fully substituted 6-electron donor anionic ligand-containing cobalt compounds are preferably hydrogen reducible and deposit in a self-limiting manner.

For CVD and ALD applications, the organometallic precursors of this invention can exhibit an ideal combination of reduced carbon incorporation, thermal stability, vapor pressure, and reactivity with the intended substrates for semiconductor applications. The organometallic precursors of this invention can desirably exhibit liquid state at delivery temperature, and/or tailored ligand spheres that can lead to better reactivity with semiconductor substrates.

The ALD and CVD precursors of this invention have the ability to reduce carbon incorporation, reduce resistivity, increase crystallinity and increase thermal stability. In particular, replacing the unsubstituted or partially substituted cyclopentadienyl ring with a fully substituted cyclopentadienyl ring (e.g., pentamethylcyclopentadienyl ring) can generate precursors that reduce carbon incorporation, reduce resistivity, increase crystallinity, and that exhibit increased thermal stability.

### DETAILED DESCRIPTION OF THE INVENTION

As indicated above, this invention relates to a compound comprising at least one metal or metalloid and at least one substituted anionic 6 electron donor ligand having sufficient substitution (i) to impart decreased carbon concentration in a film or coating produced by decomposing said compound, (ii) to impart decreased resistivity in a film or coating produced by decomposing said compound, or (iii) to impart increased crystallinity in a film or coating produced by decomposing said compound. The at least one substituted anionic 6 electron donor ligand can be fully or partially substituted.

As also indicated above, this invention relates to a compound comprising at least one metal or metalloid; at least one substituted anionic 6 electron donor ligand having sufficient substitution (i) to impart decreased carbon concentration in a film or coating produced by decomposing said compound, (ii) to impart decreased resistivity in a film or coating produced by decomposing said compound, or (iii) to impart increased crystallinity in a film or coating produced by decomposing said compound; and at least one spectator ligand selected from (i) a substituted or unsubstituted anionic 2 electron donor ligand, (ii) a substituted or unsubstituted anionic 4 electron donor ligand, (iii) a substituted or unsubstituted neutral 2 electron donor ligand, or (iv) a substituted or unsubstituted anionic 6 electron donor ligand; wherein the sum of the oxidation number of said metal or metalloid and the electric charges of said at least one substituted anionic 6 electron donor ligand and said at least one spectator ligand is equal to 0. The at least one substituted anionic 6 electron donor ligand can be fully or partially substituted.

As further indicated above, this invention relates to compounds represented by the (L₁)M(L₂)_{y} wherein M is a metal or metalloid, L₁ is a fully substituted anionic 6 electron donor ligand, L₂ is the same or different and is (i) a substituted or unsubstituted anionic 2 electron donor ligand, (ii) a substituted or unsubstituted anionic 4 electron donor ligand, (iii) a substituted or unsubstituted neutral 2 electron donor ligand, or (iv) a substituted or unsubstituted anionic 6 electron donor ligand; and y is an integer of from 1 to 3; and wherein the sum of the oxidation number of M and the electric charges of L₁ and L₂ is equal to 0.

Preferably, M is selected from cobalt (Co), rhodium (Rh), iridium (Ir), nickel (Ni), ruthenium (Ru), iron (Fe) or osmium (Os), L₁ is selected from a fully substituted cyclopentadienyl group, a fully substituted cyclopentadienyl-like group, a fully substituted cycloheptadienyl group, a fully substituted cycloheptadienyl-like group, a fully substituted pentadienyl group, a fully substituted pentadienyl-like group, a fully substituted pyrrolyl group, a fully substituted pyrrolyl-like group, a fully substituted imidazolyl group, a fully substituted imidazolyl-like group, a fully substituted pyrazolyl group, or a fully substituted pyrazolyl-like group, and L₂ is selected from (i) a substituted or unsubstituted hydrido, halo and an alkyl group having from 1 to 12 carbon atoms, (ii) a substituted or unsubstituted allyl, azaallyl, amidinate and betadiketiminate group, (iii) a substituted or unsubstituted carbonyl, phosphino, amino, alkenyl, alkynyl, nitrile and isonitrile group, and (iv) a substituted or unsubstituted cyclopentadienyl group, a substituted or unsubstituted cyclopentadienyl-like group, a substituted or unsubstituted cycloheptadienyl group, a substituted or unsubstituted cycloheptadienyl-like group, a substituted or unsubstituted pentadienyl group, a substituted or unsubstituted pentadienyl-like group, a substituted or unsubstituted pyrrolyl group, a substituted or unsubstituted pyrrolyl-like group, a substituted or unsubstituted imidazolyl group, a substituted or unsubstituted imidazolyl-like group, a substituted or unsubstituted pyrazolyl group, and a substituted or unsubstituted pyrazolyl-like group.

Referring to the compounds represented by the formula (L₁)M(L₂)_{y}, the substituted or unsubstituted cyclopentadienyl-like group is selected from cyclohexadienyl, cycloheptadienyl, cyclooctadienyl, heterocyclic group and aromatic group, the substituted or unsubstituted cycloheptadienyl-like group is selected from cyclohexadienyl, cyclooctadienyl, heterocyclic group and aromatic group, the substituted or unsubstituted pentadienyl-like group is selected from linear olefins, hexadienyl, heptadienyl and octadienyl, the substituted or unsubstituted pyrrolyl-like group is selected from pyrrolinyl, pyrazolyl, thiazolyl, oxazolyl, carbazolyl, triazolyl, indolyl and purinyl, the substituted or unsubstituted imidazoyl-like group is selected from pyrrolinyl, pyrazolyl, thiazolyl, oxazolyl, carbazolyl, triazolyl, indolyl and purinyl, the substituted or unsubstituted pyrazolyl-like group is selected from pyrrolinyl, pyrazolyl, thiazolyl, oxazolyl, carbazolyl, triazolyl, indolyl and purinyl, and the substituted or unsubstituted boratabenzene-like group is selected from methylboratabenzene, ethylboratabenzene, 1-methyl-3-ethylboratabenzene or other functionalized boratabenzene moieties.

Also, referring to the compounds represented by the formula (L₁)M(L₂)_{y}, M preferably can be selected from Co, Rh, Ir, Ru, Fe and Os. Other illustrative metals or metalloids include, for example, Ti, Zr, Hf, V, Nb, Ta, Cr, Mo, W, Mn, Tc, Re, Ni, Pd, Pt, Cu, Ag, Au, Zn, Cd, Hg, Al, Ga, Si, Ge, a Lanthanide series element or an Actinide series element.

Illustrative compounds represented by the formula (L₁)M(L₂)_{y} include, for example, Cp*CO(CO)₂, Cp*₂Ru, (Cp*)(Cp)Ru, Cp*(pyrrolyl)Ru, Cp*Rh(CO)₂, Cp*Ir(1,5-cyclooctadiene), Cp*PtMe₃, Cp*AgPR₃, Cp*CuPR₃, Cp*CpTiCl₂, Cp*₂TiCl₂, Cp*V(CO)₄, Cp*W(CO)₃H, CpCp*WH₂, Cp*₂WH₂, Cp*₂Ni, CpCp*Ni, Cp*Ni(NO), and the like. Nickel chemistries may be of special interest given their similar applications to cobalt. As used herein, Cp* represents a fully substituted cyclopentadienyl group or a fully substituted cyclopentadienyl-like group, and Cp represents an unsubstituted or partially substituted cyclopentadienyl group or an unsubstituted or partially substituted cyclopentadienyl-like group.

In the modifications to the CpCo(CO)₂ precursor, a complex with Co(I), involves significantly stronger coordination of the ligand to the metal which provides the molecule with significantly higher thermal stability, permitting for higher deposition temperatures. At elevated deposition temperatures (e.g., 300-400° C.), the tert-butylacetylene decomposes and incorporates high levels of carbon into the film.

Spectral analyses suggest that carbon incorporated into semiconductor films from precursors based on Cp ligands involves forms of carbon that are different from the Cp ring, including, but not limited to graphite and metal carbides. In order for this to occur this must necessarily involve the cleavage of C—H and C—C bonds in the Cp ring.

While not wanting to be bound by any particular theory, it is believed that replacing the C—H bond type on the (C₅H₅)⁻ ring with C—CR ¹R²R³ bond types would have multiple impacts on the chemistry of the ring. Firstly, it would eliminate olefinic C—H bonds that may be susceptible to attack by the semiconductor film. Secondly, the presence of carbon adjacent to the ring may afford better steric protection to the olefinic ring C—C bonds than the C—H bonds. Finally the presence of activating substituents on the Cp ring skeleton may also improve the stability of the ring system.

Replacing the unsubstituted or partially substituted cyclopentadienyl ring with a fully substituted cyclopentadienyl ring (e.g., pentamethylcyclopentadienyl ring or other pentaalkylcyclopentadienyl ligand in which the alkyl substituents may all be the same or different), generates precursors that reduce carbon incorporation and that exhibit increased thermal stability at the cost of a moderately reduced vapor pressure.

This invention in part provides organometallic precursor compounds and a method of processing a substrate to form a metal-based material layer, e.g., cobalt layer, on the substrate by CVD or ALD of the organometallic precursor compound. The metal-based material layer is deposited on a heated substrate by thermal or plasma enhanced dissociation of the organometallic precursor compound having the formulae above in the presence of a processing gas. The processing gas may be an inert gas, such as helium and argon, and combinations thereof. The composition of the processing gas is selected to deposit metal-based material layers, e.g., cobalt layers, as desired.

For the organometallic precursor compounds of this invention represented by the formula above, M, represents the metal to be deposited. Examples of metals which can be deposited according to this invention are Co, Rh, Ir, Ru, Fe and Os. Other illustrative metals or metalloids include, for example, Ti, Zr, Hf, V, Nb, Ta, Cr, Mo, W, Mn, Tc, Re, Fe, Ru, Os, Ni, Pd, Pt, Cu, Ag, Au, Zn, Cd, Hg, Al, Ga, Si, Ge, a Lanthanide series element or an Actinide series element.

Illustrative substituted and unsubstituted anionic ligands (L₁) useful in this invention include, for example, fully substituted 6 electron anionic donor ligands such as fully substituted cyclopentadienyl (Cp*), cycloheptadienyl, pentadienyl, pyrrolyl, boratabenzyl, pyrazolyl, imidazolyl, and the like. Cp* is a fully substituted cyclopentadienyl ring having the general formula (C₅R₅⁻) which forms a ligand with the metal, M. The precursor contains one fully substituted 6 electron anionic donor ligand group, e.g., one fully substituted cyclopentadienyl group.

Other illustrative fully substituted 6 electron anionic donor ligands include cyclodienyl complexes, e.g., cyclohexadienyl, cycloheptadienyl, cyclooctadienyl rings, heterocyclic rings, aromatic rings, such as fully substituted cyclopentadienyl ring like pentamethylcyclopentadienyl, and others, as known in the art.

Illustrative ligands (L₂) useful in this invention include, for example, (i) a substituted or unsubstituted anionic 2 electron donor ligand, (ii) a substituted or unsubstituted anionic 4 electron donor ligand, (iii) a substituted or unsubstituted neutral 2 electron donor ligand, or (iv) a substituted or unsubstituted anionic 6 electron donor ligand.

Illustrative substituted and unsubstituted anionic ligands (L₂) useful in this invention include, for example, 4 electron anionic donor ligands such as allyl, azaallyl, amidinate, betadiketiminate, and the like; 2 electron anionic donor ligands such as hybrido, halo, alkyl, and the like; and 6 electron anionic donor ligands such as a cyclopentadienyl group, a cyclopentadienyl-like group, a cycloheptadienyl group, a cycloheptadienyl-like group, a pentadienyl group, a pentadienyl-like group, a pyrrolyl group, a pyrrolyl-like group, a imidazolyl group, a imidazolyl-like group, a pyrazolyl group, and a pyrazolyl-like group.

Illustrative substituted and unsubstituted neutral ligands (L₂) useful in this invention include, for example, 2 electron neutral donor ligands such as carbonyl, phosphino, amino, alkenyl, alkynyl, nitrile, isonitrile, and the like.

Permissible substituents of the substituted ligands used herein include halogen atoms, acyl groups having from 1 to about 12 carbon atoms, alkoxy groups having from 1 to about 12 carbon atoms, alkoxycarbonyl groups having from 1 to about 12 carbon atoms, alkyl groups having from 1 to about 12 carbon atoms, amine groups having from 1 to about 12 carbon atoms or silyl groups having from 0 to about 12 carbon atoms.

Illustrative halogen atoms include, for example, fluorine, chlorine, bromine and iodine. Preferred halogen atoms include chlorine and fluorine.

Illustrative acyl groups include, for example, formyl, acetyl, propionyl, butyryl, isobutyryl, valeryl, 1-methylpropylcarbonyl, isovaleryl, pentylcarbonyl, 1-methylbutylcarbonyl, 2-methylbutylcarbonyl, 3-methylbutylcarbonyl, 1-ethylpropylcarbonyl, 2-ethylpropylcarbonyl, and the like. Preferred acyl groups include formyl, acetyl and propionyl.

Illustrative alkoxy groups include, for example, methoxy, ethoxy, n-propoxy, isopropoxy, n-butoxy, isobutoxy, sec-butoxy, tert-butoxy, pentyloxy, 1-methylbutyloxy, 2-methylbutyloxy, 3-methylbutyloxy, 1,2-dimethylpropyloxy, hexyloxy, 1-methylpentyloxy, 1-ethylpropyloxy, 2-methylpentyloxy, 3-methylpentyloxy, 4-methylpentyloxy, 1,2-dimethylbutyloxy, 1,3-dimethylbutyloxy, 2,3-dimethylbutyloxy, 1,1-dimethylbutyloxy, 2,2-dimethylbutyloxy, 3,3-dimethylbutyloxy, and the like. Preferred alkoxy groups include methoxy, ethoxy and propoxy.

Illustrative alkoxycarbonyl groups include, for example, methoxycarbonyl, ethoxycarbonyl, propoxycarbonyl, isopropoxycarbonyl, cyclopropoxycarbonyl, butoxycarbonyl, isobutoxycarbonyl, sec-butoxycarbonyl, tert-butoxycarbonyl, and the like. Preferred alkoxycarbonyl groups include methoxycarbonyl, ethoxycarbonyl, propoxycarbonyl, isopropoxycarbonyl and cyclopropoxycarbonyl.

Illustrative alkyl groups include, for example, methyl, ethyl, n-propyl, isopropyl, n-butyl, isobutyl, sec-butyl, tert-butyl, pentyl, isopentyl, neopentyl, tert-pentyl, 1-methylbutyl, 2-methylbutyl, 1,2-dimethylpropyl, hexyl, isohexyl, 1-methylpentyl, 2-methylpentyl, 3-methylpentyl, 1,1-dimethylbutyl, 2,2-dimethylbutyl, 1,3-dimethylbutyl, 2,3-dimethylbutyl, 3,3-dimethylbutyl, 1-ethylbutyl, 2-ethylbutyl, 1,1,2-trimethylpropyl, 1,2,2-trimethylpropyl, 1-ethyl-1-methylpropyl, 1-ethyl-2-methylpropyl, cyclopropyl, cyclobutyl, cyclopentyl, cyclohexyl, cyclopropylmethyl, cyclopropylethyl, cyclobutylmethyl, and the like. Preferred alkyl groups include methyl, ethyl, n-propyl, isopropyl and cyclopropyl.

Illustrative amine groups include, for example, methylamine, dimethylamine, ethylamine, diethylamine, propylamine, dipropylamine, isopropylamine, diisopropylamine, butylamine, dibutylamine, tert-butylamine, di(tert-butyl)amine, ethylmethylamine, butylmethylamine, cyclohexylamine, dicyclohexylamine, and the like. Preferred amine groups include dimethylamine, diethylamine and diisopropylamine.

Illustrative silyl groups include, for example, silyl, trimethylsilyl, triethylsilyl, tris(trimethylsilyl)methyl, trisilylmethyl, methylsilyl and the like. Preferred silyl groups include silyl, trimethylsilyl and triethylsilyl.

As indicated above, this invention also relates to mixtures comprising (i) a first organometallic precursor compound comprising at least one metal or metalloid and at least one substituted anionic 6 electron donor ligand having sufficient substitution (i) to impart decreased carbon concentration in a film or coating produced by decomposing said compound, (ii) to impart decreased resistivity in a film or coating produced by decomposing said compound, or (iii) to impart increased crystallinity in a film or coating produced by decomposing said compound, and (ii) one or more different organometallic compounds (e.g., a hafnium-containing, tantalum-containing or molybdenum-containing organometallic precursor compound).

It is believed that the presence of the above donor ligand groups enhances preferred physical properties especially reducing carbon incorporation and increased thermal stability. It is believed that appropriate choice of these substituent groups can increase organometallic precursor volatility, decrease or increase the temperature required to dissociate the precursor, and lower the boiling point of the organometallic precursor. An increased volatility of the organometallic precursor compounds ensures a sufficiently high concentration of precursor entrained in vaporized fluid flow to the processing chamber for effective deposition of a layer. The improved volatility will also allow the use of vaporization of the organometallic precursor by sublimation and delivery to a processing chamber without risk of premature dissociation. Additionally, the presence of the above donor substituent groups may also provide sufficient solubility of the organometallic precursor for use in liquid delivery systems.

It is believed that appropriate selection of the donor ligand groups for the organometallic precursors described herein allows the formation of heat decomposable organometallic compounds that are thermally stable at temperatures below about 150° C. and that are capable of thermally dissociating at temperatures above about 150° C. The organometallic precursors are also capable of dissociation in a plasma generated by supplying a power density at about 0.6 Watts/cm² or greater, or at about 200 Watts or greater for a 200 mm substrate, to a processing chamber.

The organometallic precursors described herein may deposit metal layers depending on the processing gas composition and the plasma gas composition for the deposition process. A metal layer is deposited in the presence of inert processing gases such as argon, a reactant processing gas, such as hydrogen, and combinations thereof.

It is believed that the use of a reactant processing gas, such as hydrogen, facilitates reaction with the 6 electron anionic donor group(s) to form volatile species that may be removed under low pressure, thereby removing the substituents from the precursor and depositing a metal layer on the substrate. The metal layer is preferably deposited in the presence of argon.

Illustrative reactant gases that may be used with the precursor include, for example, hydrogen, ammonia, hydrazine, 1-methylhydrazine, silane, disilane, trisilane, dichlorosilane and other silicon sources, borane, diborane, and the like. In some depositions,no reactant gases are used with the precursor.

Illustrative carrier gases that may be used with the precursor include, for example, inert gases such as N₂, He, Ne, Ar, Xe, Kr, and the like. Gases that are inert with respect to the precursor at carrier temperatures such as H₂ (does not appear to react with precursor at temperatures below 100° C.).

An exemplary processing regime for depositing a layer from the above described precursor is as follows. A precursor having the composition described herein, such as (pentamethylcyclopentadienyl)-(dicarbonyl)cobalt, and a processing gas are introduced into a processing chamber. The precursor is introduced at a flow rate between about 5 and about 500 sccm and the processing gas is introduced into the chamber at a flow rate of between about 5 and about 500 sccm. In one embodiment of the deposition process, the precursor and processing gas are introduced at a molar ratio of about 1:1. The processing chamber is maintained at a pressure between about 100 milliTorr and about 20 Torr. The processing chamber is preferably maintained at a pressure between about 100 milliTorr and about 250 milliTorr. Flow rates and pressure conditions may vary for different makes, sizes, and models of the processing chambers used.

Thermal dissociation of the precursor involves heating the substrate to a temperature sufficiently high to cause the hydrocarbon portion of the volatile metal compound adjacent the substrate to dissociate to volatile hydrocarbons which desorb from the substrate while leaving the metal on the substrate. The exact temperature will depend upon the identity and chemical, thermal, and stability characteristics of the organometallic precursor and processing gases used under the deposition conditions. However, a temperature from about room temperature to about 400° C. is contemplated for the thermal dissociation of the precursor described herein.

The thermal dissociation is preferably performed by heating the substrate to a temperature between about 100° C. and about 600° C. In one embodiment of the thermal dissociation process, the substrate temperature is maintained between about 250° C. and about 450° C. to ensure a complete reaction between the precursor and the reacting gas on the substrate surface. In another embodiment, the substrate is maintained at a temperature below about 400° C. during the thermal dissociation process.

For plasma-enhanced CVD processes, power to generate a plasma is then either capacitively or inductively coupled into the chamber to enhance dissociation of the precursor and increase reaction with any reactant gases present to deposit a layer on the substrate. A power density between about 0.6 Watts/cm² and about 3.2 Watts/cm², or between about 200 and about 1000 Watts, with about 750 Watts most preferably used for a 200 mm substrate, is supplied to the chamber to generate the plasma.

After dissociation of the precursor and deposition of the material on the substrate, the deposited material may be exposed to a plasma treatment. The plasma comprises a reactant processing gas, such as hydrogen, an inert gas, such as argon, and combinations thereof. In the plasma-treatment process, power to generate a plasma is either capacitively or inductively coupled into the chamber to excite the processing gas into a plasma state to produce plasma specie, such as ions, which may react with the deposited material. The plasma is generated by supplying a power density between about 0.6 Watts/cm² and about 3.2 Watts/cm², or between about 200 and about 1000 Watts for a 200 mm substrate, to the processing chamber.

In one embodiment the plasma treatment comprises introducing a gas at a rate between about 5 sccm and about 300 sccm into a processing chamber and generating a plasma by providing power density between about 0.6 Watts/cm² and about 3.2 Watts/cm², or a power at between about 200 Watts and about 1000 Watts for a 200 mm substrate, maintaining the chamber pressure between about 50 milliTorr and about 20 Torr, and maintaining the substrate at a temperature of between about 100° C. and about 400° C. during the plasma process.

It is believed that the plasma treatment lowers the layer's resistivity, removes contaminants, such as carbon or excess hydrogen, and densifies the layer to enhance barrier and liner properties. It is believed that species from reactant gases, such as hydrogen species in the plasma react with the carbon impurities to produce volatile hydrocarbons that can easily desorb from the substrate surface and can be purged from the processing zone and processing chamber. Plasma species from inert gases, such as argon, further bombard the layer to remove resistive constituents to lower the layers resistivity and improve electrical conductivity.

Plasma treatments are preferably not performed for metal layers, since the plasma treatment may remove the desired carbon content of the layer. If a plasma treatment for a metal layer is performed, the plasma gases preferably comprise inert gases, such as argon and helium, to remove carbon.

It is believed that depositing layers from the above identified precursors and exposing the layers to a post deposition plasma process will produce a layer with improved material properties. The deposition and/or treatment of the materials described herein are believed to have improved diffusion resistance, improved interlayer adhesion, improved thermal stability, and improved interlayer bonding.

In an embodiment of this invention, a method for metallization of a feature on a substrate is provided that comprises depositing a dielectric layer on the substrate, etching a pattern into the substrate, depositing a metal layer on the dielectric layer, and depositing a conductive metal layer on the metal layer. The substrate may be optionally exposed to reactive pre-clean comprising a plasma of hydrogen and argon to remove oxide formations on the substrate prior to deposition of the metal layer. The conductive metal is preferably copper and may be deposited by physical vapor deposition, chemical vapor deposition, or electrochemical deposition. The metal layer is deposited by the thermal or plasma enhanced dissociation of an organometallic precursor of this invention in the presence of a processing gas, preferably at a pressure less than about 20 Torr. Once deposited, the metal layer can be exposed to a plasma prior to subsequent layer deposition.

Current copper integration schemes involve a diffusion barrier with a copper wetting layer on top followed by a copper seed layer. A layer of metal gradually becoming metal rich in accordance with this invention would replace multiple steps in the current integration schemes. The metal layer is an excellent barrier to copper diffusion due to its amorphous character. The metalrich layer functions as a wetting layer and may allow for direct plating onto the metal. This single layer could be deposited in one step by manipulating the deposition parameters during the deposition. A post deposition treatment may also be employed to increase the ratio of metal in the film. Removal of one or more steps in semiconductor manufacture will result in substantial savings to the semiconductor manufacturer.

Metal films are deposited at temperatures lower than 400° C. and form no corrosive byproducts. The metal films are amorphous and are superior barriers to copper diffusion. By tuning the deposition parameters and post deposition treatment, the metal barrier can have a metal rich film deposited on top of it. This metal rich film acts as a wetting layer for copper and may allow for direct copper plating on top of the metal layer. In an embodiment, the deposition parameters may be tuned to provide a layer in which the composition varies across the thickness of the layer. For example, the layer may be metal rich at the silicon portion surface of the microchip, e.g., good barrier properties, and metal rich at the copper layer surface, e.g., good adhesive properties.

Processes that may be used in preparing the organometallic compounds of this invention include, for example, those disclosed in U.S. Pat. No. 6,605,735 B2, U.S. Patent Application Publication No. US 2004/0127732 A1, published Jul. 1, 2004, and U.S. patent application Ser. No. 61/023,131, filed Jan. 24, 2008, the disclosures of which are incorporated herein by reference. The organometallic compounds of this invention may also be prepared by conventional processes such as described in Legzdins, P. et al. Inorg. Synth. 1990, 28, 196 and references therein.

For organometallic compounds prepared by the processes above, purification can occur through recrystallization, more preferably through extraction of reaction residue (e.g., hexane) and chromatography, and most preferably through sublimation and distillation.

Those skilled in the art will recognize that numerous changes may be made to the method described in detail herein, without departing in scope or spirit from the present invention as more particularly defined in the claims below.

Examples of techniques that can be employed to characterize the organometallic compounds formed by the synthetic methods described above include, but are not limited to, analytical gas chromatography, nuclear magnetic resonance, thermogravimetric analysis, inductively coupled plasma mass spectrometry, differential scanning calorimetry, vapor pressure and viscosity measurements.

Relative vapor pressures, or relative volatility, of organometallic precursor compounds described above can be measured by thermogravimetric analysis techniques known in the art. Equilibrium vapor pressures also can be measured, for example by evacuating all gases from a sealed vessel, after which vapors of the compounds are introduced to the vessel and the pressure is measured as known in the art.

The organometallic precursor compounds described herein are well suited for preparing in-situ powders and coatings. For instance, an organometallic precursor compound can be applied to a substrate and then heated to a temperature sufficient to decompose the precursor, thereby forming a metal coating on the substrate. Applying the precursor to the substrate can be by painting, spraying, dipping or by other techniques known in the art. Heating can be conducted in an oven, with a heat gun, by electrically heating the substrate, or by other means, as known in the art. A layered coating can be obtained by applying an organometallic precursor compound, and heating and decomposing it, thereby forming a first layer, followed by at least one other coating with the same or different precursors, and heating.

Organometallic precursor compounds such as described above also can be atomized and sprayed onto a substrate. Atomization and spraying means, such as nozzles, nebulizers and others, that can be employed are known in the art.

This invention provides in part an organometallic precursor and a method of forming a metal layer on a substrate by CVD or ALD of the organometallic precursor. In one aspect of the invention, an organometallic precursor of this invention is used to deposit a metal layer at subatmospheric pressures. The method for depositing the metal layer comprises introducing the precursor into a processing chamber, preferably maintained at a pressure of less than about 20 Torr, and dissociating the precursor in the presence of a processing gas to deposit a metal layer. The precursor may be dissociated and deposited by a thermal or plasma-enhanced process. The method may further comprise a step of exposing the deposited layer to a plasma process to remove contaminants, densify the layer, and reduce the layer's resistivity.

Illustrative deposition techniques useful in this invention include, for example, CVD, PECVD (plasma enhanced CVD), ALD, PEALD (plasma enhanced ALD), AVD and any other variant that involves positioning a substrate, exposing the substrate to a precursor, the precursor alone or in conjunction with other chemical species, or in conjunction with the environment in which the substrate resides, resulting in a change to the substrate.

In preferred embodiments of the invention, an organometallic compound, such as described above, is employed in gas phase deposition techniques for forming powders, films or coatings. The compound can be employed as a single source precursor or can be used together with one or more other precursors, for instance, with vapor generated by heating at least one other organometallic compound or metal complex. More than one organometallic precursor compound, such as described above, also can be employed in a given process.

As indicated above, this invention also relates in part to a method for producing a film, coating or powder. The method includes the step of decomposing and organometallic precursor compound comprising at least one metal or metalloid and at least one substituted anionic 6 electron donor ligand having sufficient substitution (i) to impart decreased carbon concentration in said film, coating or powder, (ii) to impart decreased resistivity in said film, coating or powder, or (iii) to impart increased crystallinity in said film, coating or powder, thereby producing said film, coating or powder; as further described below.

Deposition methods described herein can be conducted to form a film, powder or coating that includes a single metal or a film, powder or coating that includes a single metal. Mixed films, powders or coatings also can be deposited, for instance mixed metal films.

Gas phase film deposition can be conducted to form film layers of a desired thickness, for example, in the range of from about 1 nm to over 1 mm. The precursors described herein are particularly useful for producing thin films, e.g., films having a thickness in the range of from about 10 nm to about 100 nm. Films of this invention, for instance, can be considered for fabricating metal electrodes, in particular as n-channel metal electrodes in logic, as capacitor electrodes for DRAM applications, and as dielectric materials.

The method also is suited for preparing layered films, wherein at least two of the layers differ in phase or composition. Examples of layered film include metal-insulator-semiconductor, and metal-insulator-metal.

In an embodiment, the invention is directed to a method that includes the step of decomposing vapor of an organometallic precursor compound described above, thermally, chemically, photochemically or by plasma activation, thereby forming a film on a substrate. For instance, vapor generated by the compound is contacted with a substrate having a temperature sufficient to cause the organometallic compound to decompose and form a film on the substrate.

The organometallic precursor compounds can be employed in chemical vapor deposition or, more specifically, in metal organic chemical vapor deposition processes known in the art. For instance, the organometallic precursor compounds described above can be used in atmospheric, as well as in low pressure, chemical vapor deposition processes. The compounds can be employed in hot wall chemical vapor deposition, a method in which the entire reaction chamber is heated, as well as in cold or warm wall type chemical vapor deposition, a technique in which only the substrate is being heated.

The organometallic precursor compounds described above also can be used in plasma or photo-assisted chemical vapor deposition processes, in which the energy from a plasma or electromagnetic energy, respectively, is used to activate the chemical vapor deposition precursor. The compounds also can be employed in ion-beam, electron-beam assisted chemical vapor deposition processes in which, respectively, an ion beam or electron beam is directed to the substrate to supply energy for decomposing a chemical vapor deposition precursor. Laser-assisted chemical vapor deposition processes, in which laser light is directed to the substrate to affect photolytic reactions of the chemical vapor deposition precursor, also can be used.

The method of the invention can be conducted in various chemical vapor deposition reactors, such as, for instance, hot or cold-wall reactors, plasma-assisted, beam-assisted or laser-assisted reactors, as known in the art.

Given the ability to do CVD with multiple chemicals simultaneously (e.g., a stream of 95% Cp*CO(CO)₂ and 5% CpPtMe₃), the CVD process may provide the ability to deposit alloys more easily and with a range of compositions through the film (if the concentrations change as a function of time) than PVD based approaches.

Examples of substrates that can be coated employing the method of the invention include solid substrates such as metal substrates, e.g., Al, Ni, Ti, Co, Pt, metal silicides, e.g., TiSi₂, CoSi₂, NiSi₂; semiconductor materials, e.g., Si, SiGe, GaAs, InP, diamond, GaN, SiC; insulators, e.g., SiO₂, Si₃N₄, HfO₂, Ta₂O₅, Al₂O₃, barium strontium titanate (BST); or on substrates that include combinations of materials. In addition, films or coatings can be formed on glass, ceramics, plastics, thermoset polymeric materials, and on other coatings or film layers. In preferred embodiments, film deposition is on a substrate used in the manufacture or processing of electronic components. In other embodiments, a substrate is employed to support a low resistivity conductor deposit that is stable in the presence of an oxidizer at high temperature or an optically transmitting film.

With regard to deposition conditions, useful substates include, but are not limited to, semiconductor substrates such as Si(100), Si(111), other orientations of crystalline Si, doped crystalline Si (e.g., P, B, As, Ge, Al, Ga as dopants), SiO₂, Ge, SiGe, TaN, Ta₃N₅, TaCₓN_{y}, and the like.

Non-semiconductor substrates such as other glasses, ceramics, metals, and the like, that may find application in solar, flat panel, and/or fuel cell applications can also be utilized.

The method of this invention can be conducted to deposit a film on a substrate that has a smooth, flat surface. In an embodiment, the method is conducted to deposit a film on a substrate used in wafer manufacturing or processing. For instance, the method can be conducted to deposit a film on patterned substrates that include features such as trenches, holes or vias. Furthermore, the method of the invention also can be integrated with other steps in wafer manufacturing or processing, e.g., masking, etching and others.

In an embodiment of this invention, a plasma assisted ALD (PEALD) method has been developed for using the organometallic precursors to deposit metal films. The solid precursor can be sublimed under the flow of an inert gas to introduce it into a CVD chamber. Metal films are grown on a substrate with the aid of a hydrogen plasma.

Chemical vapor deposition films can be deposited to a desired thickness. For example, films formed can be less than 1 micron thick, preferably less than 500 nanometers and more preferably less than 200 nanometers thick. Films that are less than 50 nanometers thick, for instance, films that have a thickness between about 0.1 and about 20 nanometers, also can be produced.

Organometallic precursor compounds described above also can be employed in the method of the invention to form films by ALD processes or atomic layer nucleation (ALN) techniques, during which a substrate is exposed to alternate pulses of precursor, oxidizer and inert gas streams. Sequential layer deposition techniques are described, for example, in U.S. Pat. No. 6,287,965 and in U.S. Pat. No. 6,342,277. The disclosures of both patents are incorporated herein by reference in their entirety.

For example, in one ALD cycle, a substrate is exposed, in step-wise manner, to: a) an inert gas; b) inert gas carrying precursor vapor; c) inert gas; and d) oxidizer, alone or together with inert gas. In general, each step can be as short as the equipment will permit (e.g. milliseconds) and as long as the process requires (e.g. several seconds or minutes). The duration of one cycle can be as short as milliseconds and as long as minutes. The cycle is repeated over a period that can range from a few minutes to hours. Film produced can be a few nanometers thin or thicker, e.g., 1 millimeter (mm).

In an example, the deposition of cobalt films using Cp*Co(CO)₂ can be conducted at various processing conditions such as a temperature between 200° C. and 1000° C., preferably between 300° C. and 500° C.; a pressure between 0.001 and 1000 Torr, preferably between 0.1 to 100 Torr; a mole fraction of Cp*Co(CO)₂ between 0 and 1, preferably between 0.000006 and 0.01; vaporization temperature of Cp*Co(CO)₂ between 0° C. and 200° C., preferably between 30° C. and 100° C.; and a mole fraction of hydrogen between 0 and 1, preferably between 0.5 and 1.

This invention includes a method for forming a metal-containing material on a substrate, e.g., a microelectronic device structure, from an organometallic precursor of this invention, said method comprising vaporizing said organometallic precursor to form a vapor, and contacting the vapor with the substrate to form said metal material thereon. After the metal is deposited on the substrate, the substrate may thereafter be metallized with copper or integrated with a ferroelectric thin film.

In an embodiment of this invention, a method is provided for fabricating a microelectronic device structure, said method comprising vaporizing an organometallic precursor compound to form a vapor, and contacting said vapor with a substrate to deposit a metal-containing film on the substrate, and thereafter incorporating the metal-containing film into a semiconductor integration scheme; wherein said organometallic precursor compound comprises at least one metal or metalloid and at least one substituted anionic 6 electron donor ligand having sufficient substitution (i) to impart decreased carbon concentration in said metal-containing film, (ii) to impart decreased resistivity in said metal-containing film, or (iii) to impart increased crystallinity in said metal-containing film.

The method of the invention also can be conducted using supercritical fluids. Examples of film deposition methods that use supercritical fluid that are currently known in the art include chemical fluid deposition; supercritical fluid transport-chemical deposition; supercritical fluid chemical deposition; and supercritical immersion deposition.

Chemical fluid deposition processes, for example, are well suited for producing high purity films and for covering complex surfaces and filling of high-aspect-ratio features. Chemical fluid deposition is described, for instance, in U.S. Pat. No. 5,789,027. The use of supercritical fluids to form films also is described in U.S. Pat. No. 6,541,278 B2. The disclosures of these two patents are incorporated herein by reference in their entirety.

In an embodiment of the invention, a heated patterned substrate is exposed to one or more organometallic precursor compounds, in the presence of a solvent, such as a near critical or supercritical fluid, e.g., near critical or supercritical CO₂. In the case of CO₂, the solvent fluid is provided at a pressure above about 1000 psig and a temperature of at least about 30° C.

The precursor is decomposed to form a metal film on the substrate. The reaction also generates organic material from the precursor. The organic material is solubilized by the solvent fluid and easily removed away from the substrate.

In an example, the deposition process is conducted in a reaction chamber that houses one or more substrates. The substrates are heated to the desired temperature by heating the entire chamber, for instance, by means of a furnace. Vapor of the organometallic compound can be produced, for example, by applying a vacuum to the chamber. For low boiling compounds, the chamber can be hot enough to cause vaporization of the compound. As the vapor contacts the heated substrate surface, it decomposes and forms a metal film. As described above, an organometallic precursor compound can be used alone or in combination with one or more components, such as, for example, other organometallic precursors, inert carrier gases or reactive gases.

In an embodiment of this invention, a method is provided for forming a metal-containing material on a substrate from an organometallic precursor compound, said method comprising vaporizing said organometallic precursor compound to form a vapor, and contacting the vapor with the substrate to form said metal material thereon; wherein said organometallic precursor compound comprises at least one metal or metalloid and at least one substituted anionic 6 electron donor ligand having sufficient substitution (i) to impart decreased carbon concentration in said metal-containing film, (ii) to impart decreased resistivity in said metal-containing film, or (iii) to impart increased crystallinity in said metal-containing film.

In another embodiment of this invention, a method is provided for processing a substrate in a processing chamber, said method comprising (i) introducing an organometallic precursor compound into said processing chamber, (ii) heating said substrate to a temperature of about 100° C. to about 400° C., and (iii) dissociating said organometallic precursor compound in the presence of a processing gas to deposit a metal layer on said substrate; wherein said organometallic precursor compound comprises at least one metal or metalloid and at least one substituted anionic 6 electron donor ligand having sufficient substitution (i) to impart decreased carbon concentration in said metal-containing layer, (ii) to impart decreased resistivity in said metal-containing layer, or (iii) to impart increased crystallinity in said metal-containing layer.

In a system that can be used in producing films by the method of the invention, raw materials can be directed to a gas-blending manifold to produce process gas that is supplied to a deposition reactor, where film growth is conducted. Raw materials include, but are not limited to, carrier gases, reactive gases, purge gases, precursor, etch/clean gases, and others. Precise control of the process gas composition is accomplished using mass-flow controllers, valves, pressure transducers, and other means, as known in the art. An exhaust manifold can convey gas exiting the deposition reactor, as well as a bypass stream, to a vacuum pump. An abatement system, downstream of the vacuum pump, can be used to remove any hazardous materials from the exhaust gas. The deposition system can be equipped with in-situ analysis system, including a residual gas analyzer, which permits measurement of the process gas composition. A control and data acquisition system can monitor the various process parameters (e.g., temperature, pressure, flow rate, etc.).

The organometallic precursor compounds described above can be employed to produce films that include a single metal or a film that includes a single metal. Mixed films also can be deposited, for instance mixed metal films. Such films are produced, for example, by employing several organometallic precursors. Metal films also can be formed, for example, by using no carrier gas, vapor or other sources of oxygen.

Films formed by the methods described herein can be characterized by techniques known in the art, for instance, by X-ray diffraction, Auger spectroscopy, X-ray photoelectron emission spectroscopy, atomic force microscopy, scanning electron microscopy, and other techniques known in the art. Resistivity and thermal stability of the films also can be measured, by methods known in the art.

In addition to their use in semiconductor applications as chemical vapor or atomic layer deposition precursors for film depositions, the organometallic compounds of this invention may also be useful, for example, as catalysts, fuel additives and in organic syntheses.

Various modifications and variations of this invention will be obvious to a worker skilled in the art and it is to be understood that such modifications and variations are to be included within the purview of this application and the spirit and scope of the claims.

### EXAMPLE 1

### Precursor Synthesis: Dicarbonyl-(n⁵Pentamethylcyclopentadienyl)Cobalt(I)

All glassware was dried in a 1000° C. oven, assembled and kept under a nitrogen purge throughout reaction. All solvents used were anhydrous.

To a 100 mL, three-neck round bottom flask equipped with a reflux condenser, teflon stir bar, gas inlet, glass stopper and septum was added cobalt octacarbonyl (6.0 g; 17.5 mmol). The septum was replaced and assembled reaction flask purged an additional 5 minutes. Dichloromethane (50 mL) was then canulated into reaction flask and solution stirred for 5 minutes. To the reaction solution was added 1,2,3,4,5-pentamethylcyclopentadiene (3.1 g; 22.7 mmol) and 1,3-cyclohexadiene ((2.5 mL; 26.2 mmol). Septum was replaced with glass stopper and reaction mixture was stirred and brought to a gentle reflux which was maintained for one (1) hour. The reaction was cooled just until reflux stopped followed by a second addition of 1,2,3,4,5-pentamethylcyclopentadiene (2.4 g; 17.6 mmol). Reflux was then continued for another two (2) hours. The reaction was then cooled and stirred overnight at room temperature.

The condenser was and replaced with a gas inlet and the volatile material removed under reduced pressure maintaining a flask temperature of 15-20° C. The dark red crude material (7.89 g) was then transferred into a glovebox. The crude material was dissolved in hexanes (30 mL) and loaded into a column of alumina (Brockman I—neutral) previously rinsed with hexanes (200 mL). The title compound was then eluted as an orange-brown band with hexanes (800 mL). The solvent was removed under reduced pressure yielding deep red crystals of the title compound (6.09 g; 70% based on Co₂(CO)₈). The synthesis can be represented as follows:

Co₂(CO)₈+2C₅Me₅H+C₆H₈ [symbol] 2[Co(n⁵-C5Me5)(CO)₂+C₆H₁₀+4CO

Analytical Characterization:

¹H NMR spectrum was taken using a Bruker Avance 300 Spectrometer

¹H NMR (C₆D₆) δ 1.6 (s, 5 CH3)

### EXAMPLE 2

### Thin Film Deposition: Dicarbonyl-(n⁵-Pentamethylcyclopentadienyl)Cobalt(I)

The film deposition depends on the specific application in question. The present thin films were deposited by chemical vapor deposition, using CpCo(CO)₂ and Cp*Co(CO)₂. A detailed description of the reactor used has been previously reported (J. Atwood, D. C. Hoth, D. A. Moreno, C. A. Hoover, S. H. Meiere, D. M. Thompson, G. B. Piotrowski, M. M. Litwin, J. Peck, Electrochemical Society Proceedings 2003-08, (2003) 847). The precursors were vaporized using 100 sccm of Ar, at 500 Torr. Film deposition was conducted at a reactor pressure or 5 Torr. A mixture of argon and hydrogen, with a combined flow of 750 sccm, was used as the process gas. The flow of argon and hydrogen was 350 and 400 sccm, respectively. The substrates were 3″ Si wafers, with 250 nm of oxide. The vaporization temperature of the precursors was adjusted to control the mole fraction of precursor in the process gas. Substrates were exposed to the process gas for a period of time sufficient to deposit the desired film thickness. The composition of the films was ascertained by x-ray photoelectron spectroscopy (XPS).

A series of experiments were conducted, at a variety of substrate temperatures (between 350° C. to 450° C.) and precursor concentrations (precursor mole fractions were between 2E-4 and 2E-5). For each set of process conditions, films were deposited using both precursors. The sheet resistance, thickness and composition of the resulting films were measured.

XPS indicated that within the range of process conditions studied, films deposited using Cp*CO(CO)₂ exhibited decreased carbon incorporation, decreased resistivity and increased crystallinity, compared to film deposited using CpCo(CO)₂ at the same conditions (e.g., temperature, precursor concentration). A comparison of experiments conducted at the same process conditions showed that films deposited using Cp*CO(CO)₂ exhibited lower carbon incorporation and resistivity, compared to films deposited using CpCo(CO)₂. Within the range of conditions studied, the films deposited using CpCo(CO)₂ exhibited a minimum resistivity of 600 micro ohms cm and a minimum carbon concentration of 40%. In contrast, within the range of conditions studied, the films deposited using Cp*CO(CO)₂ exhibited a minimum resistivity of 25 micro ohms cm and a minimum carbon concentration of 10%.

A comparison of specific examples also illustrates the difference in resistivity and carbon incorporation. One experiment (i.e., 20070320A) was conducted using CpCo(CO)₂. At the center of the substrate from run 20070320A, the resistivity was about 1000 micro ohms cm and the film contained approximately 50% carbon. Another experiment (i.e., 20070323A) was conducted using Cp*Co(CO)₂. At the center of the substrate from run 20070323A, the resistivity was about 150 micro ohms cm and the film contained less than 20% carbon.

Depth profiles were collected by etching (sputtering) the film using an argon ion gun, in between XPS scans. Within the range of process conditions studied, the XPS depth profiles of the films deposited using Cp*CO(CO)₂ show a decrease in carbon incorporation, compared to the films deposited using CpCo(CO)₂. According to XPS, the amount of carbon in the films deposited using CpCo(CO)₂ was approximately 50-60%. The amount of carbon in the films deposited using Cp*CO(CO)₂ was approximately 10-20%. The sheet resistance of the films deposited using Cp*CO(CO)₂ was measured with a 4 point probe and the thickness of the films was determined by scanning electron microscopy (SEM). The sheet resistance data for some of the films deposited using Cp*Co(CO)₂ varied by a factor of 100, with the maximum value occurring at the center of the wafer. In contrast, the corresponding thickness of these films varied by less than a factor of 2. Film resistivity is calculated by multiplying the sheet resistance and corresponding thickness. For the aforementioned films deposited using Cp*Co(CO)₂, the resistivity varied by a factor of greater than 50, with the maximum occurring at the center of the wafer. A change in film resistivity is generally attributed to a change in composition (e.g., impurity) and/or morphology (e.g., crystallinity, grain size, roughness). Since the maximum resistivity for some of the samples occurred at the center of the wafer and that was where the composition was measured, this implies that within the regions of minimum resistivity the films possess less carbon that at the center of the wafer. This implication assumes that the variation in resistivity is not attributed to a change in film morphology.

While the invention has been described in detail with reference to specific embodiments thereof, it will become apparent to one skilled in the art that various changes and modifications can be make, and equivalents employed, without departing from the scope of the appended claims.

1. A compound comprising at least one metal or metalloid and at least one substituted anionic 6 electron donor ligand having sufficient substitution (i) to impart decreased carbon concentration in a film or coating produced by decomposing said compound, (ii) to impart decreased resistivity in a film or coating produced by decomposing said compound, or (iii) to impart increased crystallinity in a film or coating produced by decomposing said compound.

2. The compound of claim 1 wherein said at least one substituted anionic 6 electron donor ligand is fully or partially substituted.

3. The compound of claim 1 further comprising at least one spectator ligand selected from (i) a substituted or unsubstituted anionic 2 electron donor ligand, (ii) a substituted or unsubstituted anionic 4 electron donor ligand, (iii) a substituted or unsubstituted neutral 2 electron donor ligand, or (iv) a substituted or unsubstituted anionic 6 electron donor ligand; wherein the sum of the oxidation number of said metal or metalloid and the electric charges of said at least one substituted anionic 6 electron donor ligand and said at least one spectator ligand is equal to 0. The at least one substituted anionic 6 electron donor ligand can be fully or partially substituted.

4. A compound represented by the formula (L₁)M(L₂)y wherein M is a metal or metalloid, L₁ is a fully substituted anionic 6 electron donor ligand, L₂ is the same or different and is (i) a substituted or unsubstituted anionic 2 electron donor ligand, (ii) a substituted or unsubstituted anionic 4 electron donor ligand, (iii) a substituted or unsubstituted neutral 2 electron donor ligand, or (iv) a substituted or unsubstituted anionic 6 electron donor ligand; and y is an integer of from 1 to 3; and wherein the sum of the oxidation number of M and the electric charges of L₁ and L₂ is equal to 0.

5. The compound of claim 4 wherein M is selected from cobalt (Co), rhodium (Rh), iridium (Ir), nickel (Ni), ruthenium (Ru), iron (Fe) or osmium (Os), L₁ is selected from a fully substituted cyclopentadienyl group, a fully substituted cyclopentadienyl-like group, a fully substituted cycloheptadienyl group, a fully substituted cycloheptadienyl-like group, a fully substituted pentadienyl group, a fully substituted pentadienyl-like group, a fully substituted pyrrolyl group, a fully substituted pyrrolyl-like group, a fully substituted imidazolyl group, a fully substituted imidazolyl-like group, a fully substituted pyrazolyl group, and a fully substituted pyrazolyl-like group, and L₂ is selected from (i) a substituted or unsubstituted hydrido, halo and an alkyl group having from 1 to 12 carbon atoms, (ii) a substituted or unsubstituted allyl, azaallyl, amidinate and betadiketiminate, (iii) a substituted or unsubstituted carbonyl, phosphino, amino, alkenyl, alkynyl, nitrile and isonitrile, and (iv) a a substituted or unsubstituted cyclopentadienyl group, a substituted or unsubstituted cyclopentadienyl-like group, a substituted or unsubstituted cycloheptadienyl group, a substituted or unsubstituted cycloheptadienyl-like group, a substituted or unsubstituted pentadienyl group, a substituted or unsubstituted pentadienyl-like group, a substituted or unsubstituted pyrrolyl group, a substituted or unsubstituted pyrrolyl-like group, a substituted or unsubstituted imidazolyl group, a substituted or unsubstituted imidazolyl-like group, a substituted or unsubstituted pyrazolyl group, and a substituted or unsubstituted pyrazolyl-like group.

6. The compound of claim 5 wherein the substituted or unsubstituted cyclopentadienyl-like group is selected from cyclohexadienyl, cycloheptadienyl, cyclooctadienyl, heterocyclic group and aromatic group, the substituted or unsubstituted cycloheptadienyl-like group is selected from cyclohexadienyl, cyclooctadienyl, heterocyclic group and aromatic group, the substituted or unsubstituted pentadienyl-like group is selected from linear olefins, hexadienyl, heptadienyl and octadienyl, the substituted or unsubstituted pyrrolyl-like group is selected from pyrrolinyl, pyrazolyl, thiazolyl, oxazolyl, carbazolyl, triazolyl, indolyl and purinyl, the substituted or unsubstituted imidazoyl-like group is selected from pyrrolinyl, pyrazolyl, thiazolyl, oxazolyl, carbazolyl, triazolyl, indolyl and purinyl, the substituted or unsubstituted pyrazolyl-like group is selected from pyrrolinyl, pyrazolyl, thiazolyl, oxazolyl, carbazolyl, triazolyl, indolyl and purinyl, and the substituted or unsubstituted boratabenzene-like group is selected from methylboratabenzene, ethylboratabenzene, 1-methyl-3-ethylboratabenzene or other functionalized boratabenzene moieties.

7. The compound of claim 4 represented by the formula L₁Co(L₂)₂.

8. The compound of claim 4 which is a liquid at 20° C.

9. The compound of claim 4 selected from Cp*CO(CO)₂, Cp*₂Ru, (Cp*)(Cp)Ru, Cp*(pyrrolyl)Ru, Cp*Rh(CO)₂, Cp*Ir(1,5-cyclooctadiene), Cp*PtMe₃, Cp*AgPR₃, Cp*CuPR₃, Cp*CpTiCl₂, Cp*₂TiCl₂, Cp*V(CO)₄, Cp*W(CO)₃H, CpCp*WH₂, Cp*₂WH₂, Cp*₂Ni, CpCp*Ni, and Cp*Ni(NO).

10. The compound of claim 4 that has undergone hydrogen reduction.

11. A method for producing a film, coating or powder by by decomposing an organometallic precursor compound, thereby producing said film, coating or powder; wherein said organometallic precursor compound comprises at least one metal or metalloid and at least one substituted anionic 6 electron donor ligand having sufficient substitution (i) to impart decreased carbon concentration in said film, coating or powder, (ii) to impart decreased resistivity in said film, coating or powder, or (iii) to impart increased crystallinity in said film, coating or powder.

12. The method of claim 11 wherein the decomposing of said organometallic precursor compound is thermal, chemical, photochemical or plasma-activated.

13. The method of claim 11 wherein said organometallic precursor compound is vaporized and the vapor is directed into a deposition reactor housing a substrate.

14. The method of claim 13 wherein said substrate is comprised of a material selected from the group consisting of a metal, a metal silicide, a semiconductor, an insulator and a barrier material.

15. The method of claim 14 wherein said substrate is a patterned wafer.

16. The method of claim 11 wherein said film, coating or powder is produced by a gas phase deposition.

17. The method of claim 14 wherein a metal layer is deposited on said substrate by plasma assisted chemical vapor deposition or plasma assisted atomic layer deposition.

18. A method for processing a substrate in a processing chamber, said method comprising (i) introducing an organometallic precursor compound into said processing chamber, (ii) heating said substrate to a temperature of about 100° C. to about 600° C., and (iii) reacting said organometallic precursor compound in the presence of a processing gas to deposit a metal-containing layer on said substrate; wherein said organometallic precursor compound comprises at least one metal or metalloid and at least one substituted anionic 6 electron donor ligand having sufficient substitution (i) to impart decreased carbon concentration in said metal-containing layer, (ii) to impart decreased resistivity in said metal-containing layer, or (iii) to impart increased crystallinity in said metal-containing layer.

19. The method of claim 18 wherein said metal-containing layer is deposited on said substrate by chemical vapor deposition or atomic layer deposition.

20. The method of claim 18 wherein said metal-containing layer is deposited on said substrate by plasma assisted chemical vapor deposition or plasma assisted atomic layer deposition.

21. The method of claim 18 wherein said processing gas is selected from hydrogen, argon, helium, or combinations thereof.

22. The method of claim 18 furthering comprising depositing a second metal-containing layer on the metal-containing layer.

23. The method of claim 22 wherein the second metal-containing layer comprises copper and is deposited by an electroplating technique.

24. A method for forming a metal-containing material on a substrate from an organometallic precursor compound, said method comprising vaporizing said organometallic precursor compound to form a vapor, and contacting the vapor with the substrate to form said metal-containing material thereon; wherein said organometallic precursor compound comprises at least one metal or metalloid and at least one substituted anionic 6 electron donor ligand having sufficient substitution (i) to impart decreased carbon concentration in said metal-containing material, (ii) to impart decreased resistivity in said metal-containing material, or (iii) to impart increased crystallinity in said metal-containing material.

25. The method of claim 24 wherein the substrate comprises a microelectronic device structure.

26. The method of claim 24 wherein said organometallic precursor compound is deposited on said substrate, and the substrate is thereafter metallized with copper or integrated with a ferroelectric thin film.

27. A method of fabricating a microelectronic device structure, said method comprising vaporizing an organometallic precursor compound to form a vapor, and contacting said vapor with a substrate to deposit a metal-containing film on the substrate, and thereafter incorporating the metal-containing film into a semiconductor integration scheme; wherein said organometallic precursor compound comprises at least one metal or metalloid and at least one substituted anionic 6 electron donor ligand having sufficient substitution (i) to impart decreased carbon concentration in said metal-containing film, (ii) to impart decreased resistivity in said metal-containing film, or (iii) to impart increased crystallinity in said metal-containing film.

28. A mixture comprising (i) a first organometallic precursor compound comprising at least one metal or metalloid and at least one substituted anionic 6 electron donor ligand having sufficient substitution (i) to impart decreased carbon concentration in a film or coating produced by decomposing said compound, (ii) to impart decreased resistivity in a film or coating produced by decomposing said compound, or (iii) to impart increased crystallinity in a film or coating produced by decomposing said compound, and (ii) one or more different organometallic compounds.

29. The mixture of claim 28 wherein said first organometallic precursor compound is represented by the formula (L₁)M(L₂)_{y} wherein M is a metal or metalloid, L₁ is a fully substituted anionic 6 electron donor ligand, L₂ is the same or different and is (i) a substituted or unsubstituted anionic 2 electron donor ligand, (ii) a substituted or unsubstituted anionic 4 electron donor ligand, (iii) a substituted or unsubstituted neutral 2 electron donor ligand, or (iv) a substituted or unsubstituted anionic 6 electron donor ligand; and y is an integer of from 1 to 3; and wherein the sum of the oxidation number of M and the electric charges of L₁ and L₂ is equal to 0; and said one or more different organometallic precursor compounds comprise a haffnium-containing, tantalum-containing or molybdenum-containing organometallic precursor compound.

30. The mixture of claim 29 wherein said first organometallic precursor compound is selected from L₁Co(L₂)₂.
